(19) United States
(12) Patent Application Publication
(10) Pub. No.: US 2019/0027370 A1
(43) Pub. Date: Jan. 24, 2019

(54) SHAPED CAVITY FOR EPITAXIAL SEMICONDUCTOR GROWTH

(71) Applicant: GLOBALFOUNDRIES Inc., Grand Cayman (KY)

(72) Inventors: George R. Mulfinger, Gansevoort, NY (US); Hyun-Jin Cho, San Jose, CA (US); Anil Kumar, Poway, CA (US); Timothy J. McArdle, Ballston Lake, NY (US)

(21) Appl. No.: 15/653,594

(22) Filed: Jul. 19, 2017

(51) Int. Cl. H01L 21/306; H01L 29/08; H01L 21/02; H01L 29/06; H01L 29/66

(52) U.S. Cl. CPC H01L 21/30604; H01L 29/0847; H01L 29/66045; H01L 21/02636; H01L 29/0657; H01L 21/02532

(57) ABSTRACT

Methods of forming a field-effect transistor. A gate structure is formed that overlaps with a channel region in a semiconductor fin. The semiconductor fin is etched with a first etching process to form a cavity extending through the semiconductor fin and into a substrate fin underlying the semiconductor fin. After the cavity is formed, the semiconductor fin is etched selective to the substrate fin with a second etching process to widen a portion of the cavity.

### BACKGROUND

The present invention relates to semiconductor device fabrication and integrated circuits and, more specifically, to methods of forming a field effect transistor.

Device structures for a field-effect transistor generally include a body region, a source and a drain defined in the body region, and a gate structure configured to apply a control voltage that switches carrier flow in a channel formed in the body region. When a control voltage that is greater than a designated threshold voltage is applied, carrier flow occurs in the channel between the source and drain to produce a device output current.

Epitaxial semiconductor films may be used to modify the performance of field-effect transistors. For example, an epitaxial semiconductor film can be used to increase the carrier mobility through the channel of a field-effect transistor by inducing stresses in the channel. In a p-channel field-effect transistor, hole mobility can be enhanced by applying a compressive stress to the channel. One way in which the compressive stress can be applied is by embedding an epitaxial semiconductor material, such as silicon-germanium, at the ends of the channel. Similarly, electron mobility can be enhanced in an n-channel field-effect transistor by applying a tensile longitudinal stress to the channel. One way in which the tensile stress can be applied is by embedding an embedding an epitaxial semiconductor material, such as silicon doped with carbon, at the ends of the channel. The embedded stressors may operate as portions of source and drain regions of the field effect transistor, and as a dopant supply for other portions of the source and drain regions.

When embedded source and drain regions are in closer proximity to the channel region, transistor performance generally improves because of increased strain. However, with a short gate length, there is a point at which closer-embedded source and drain proximity to the channel results in transistor performance degradation due to increased off-state leakage. Moving forward to smaller transistor technologies, it may be desirable to shrink to shorter gate lengths, while maintaining strain from embedded source and drain regions without suffering increases in off-state leakage.

Accordingly, improved methods of forming a field effect transistor are needed.

### SUMMARY

In an embodiment of the invention, a method is provided for forming a field-effect transistor. A gate structure is formed that overlaps with a channel region in a semiconductor fin. The semiconductor fin is etched with a first etching process to form a cavity extending through the semiconductor fin and into a substrate fin underlying the semiconductor fin. After the cavity is formed, the semiconductor fin is etched selective to the substrate fin with a second etching process to widen a portion of the cavity.

### BRIEF DESCRIPTION OF THE DRAWINGS

The accompanying drawings, which are incorporated in and constitute a part of this specification, illustrate various embodiments of the invention and, together with a general description of the invention given above and the detailed description of the embodiments given below, serve to explain the embodiments of the invention.

FIGS. 1-4 are cross-sectional views of a structure at successive fabrication stages of a processing method in accordance with embodiments of the invention.

### DETAILED DESCRIPTION

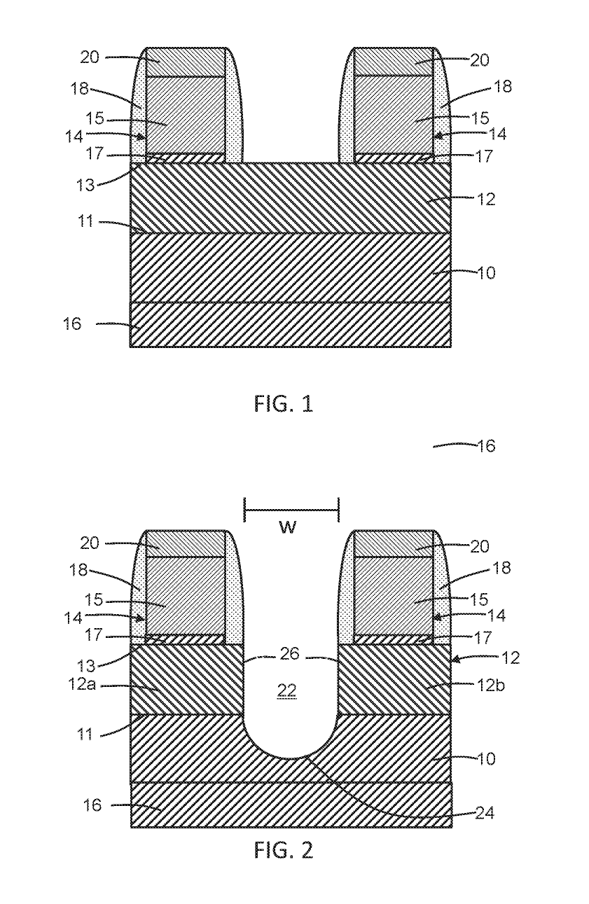

With reference to FIG. 1 and in accordance with embodiments of the invention, a substrate fin 10 and a semiconductor fin 12 are located on a top surface of a substrate 16. The substrate 16 may be, for example, a bulk semiconductor substrate. The substrate fin 10 and the semiconductor fin 12, which converge along an interface 11, are composed of two different semiconductor materials in which the semiconductor material constituting the semiconductor fin 12 etches selectively to the semiconductor material constituting the substrate fin 10. In an embodiment, the semiconductor material constituting the semiconductor fin 12 etches at a higher rate than the semiconductor material constituting the substrate fin 10 when etched with a given etch chemistry. For example, the semiconductor fin 12 may be composed of single-crystal silicon-germanium (SiGe) and the substrate fin 10 may be composed of single-crystal elemental silicon. As used herein, the term “selective” in reference to a material removal process (e.g., etching) denotes that, with an appropriate etchant choice, the material removal rate (i.e., etch rate) for the targeted material is greater than the removal rate for at least another material exposed to the material removal process. The semiconductor fin 12 may be formed, for example, by a replacement fin process after the substrate fin 10 is patterned from a layer of its constituent semiconductor material by a masked etching process. The semiconductor fin 12 and the substrate fin 10 project vertically from the substrate 16, and may have common sidewalls.

Gate structures 14 of a multi-gate field effect transistor are arranged on a top surface 13 of the semiconductor fin 12 and overlap with the semiconductor fin 12 at spaced apart locations. The gate structures 14 may also be located on trench isolation (not shown) in the substrate fin 10 adjacent to the semiconductor fin 12. Each gate structure 14 includes a gate electrode 15 and a gate dielectric 17 interposed between the gate electrode and the substrate fin 10. The gate electrode 15 may be composed of polycrystalline silicon (i.e., polysilicon), or may include one or more conformal barrier metal layers and/or work function metal layers composed of conductors, such as metals (e.g., tungsten (W)) and/or metal nitrides or carbides (e.g., titanium nitride (TiN) and titanium aluminum carbide (TiAlC)). The gate dielectric 17 may be composed of a dielectric material, such as silicon dioxide (SiO₂) or a high-k dielectric material like hafnium oxide (HfO₂). The gate structures 14 may be functional gate structures or, in the alternative, sacrificial gate structures that are removed and replaced in a replacement metal gate process. The term “sacrificial gate structure” as used herein refers to a placeholder structure for a functional gate structure to be subsequently formed. The term “functional gate structure” as used herein refers to a permanent gate structure used to control output current (i.e., flow of carriers in the channel) of a semiconductor device.

Sidewall spacers 18 are positioned on the top surface of the semiconductor fin 12 at locations adjacent to the vertical sidewalls of each gate structure 14. The sidewall spacers 18 may be composed of a dielectric material, such as a low-k dielectric material like silicon oxycarbonitride (SiOCN), deposited as a conformal layer by atomic layer deposition (ALD) and etched with a directional etching process, such as reactive ion etching (ME). A gate cap 20 is arranged on the top surface of the gate electrode of each gate structure 14 and in a space laterally between the sidewall spacers 18. The gate caps 20 may be composed of a dielectric material, such as silicon nitride (Si₃N₄), deposited by chemical vapor deposition (CVD), and are present to prevent epitaxial grown on the gate structures 14 during subsequent source and drain formation.

With reference to FIG. 2 in which like reference numerals refer to like features in FIG. 1 and at a subsequent fabrication stage of the processing method, a section of the semiconductor fin 12 between the gate structures 14 is removed to form a cavity 22 that extends in a vertical direction completely through the semiconductor fin 12 and to a shallow depth of penetration into the substrate fin 10. Additional sections of the semiconductor fin 12 may be removed between the gate structures 14 and adjacent gate structures (not shown). The cavity 22 may be formed using a reactive ion etching (ME) process with a suitable etch chemistry, such as a RIE process using carbon tetrafluouride (CH₄) as a source gas to generate the reactive ions. The etching process is a dry anisotropic etch and is self-aligned by the sidewall spacers 18 on the gate structures 14.

The cavity 22 divides the semiconductor fin 12 into distinct channel regions 12a, 12b. One of the channel regions 12a is associated with one of the gate structures 14, and the other of the channel regions 12b is associated with the adjacent gate structure 14. During operation with a control voltage applied to the gate electrodes of the gate structures 14, carrier flow occurs in the channel regions 12a, 12b.

A bottom surface 24 of the portion of the cavity 22 in the substrate fin 10 and below the interface 11 may have a u-shaped curvature. Above the interface 11, the channel regions 12a, 12b are accessible at their side surfaces 26 through the cavity 22. The side surfaces 26 the channel regions 12a, 12b in the portion of the cavity 22 extending through the semiconductor fin 12 are contained in planes spaced apart from each other by the width, w, of the cavity 22, and the planes containing the side surfaces 26 may have a vertical orientation and may be oriented parallel to each other.

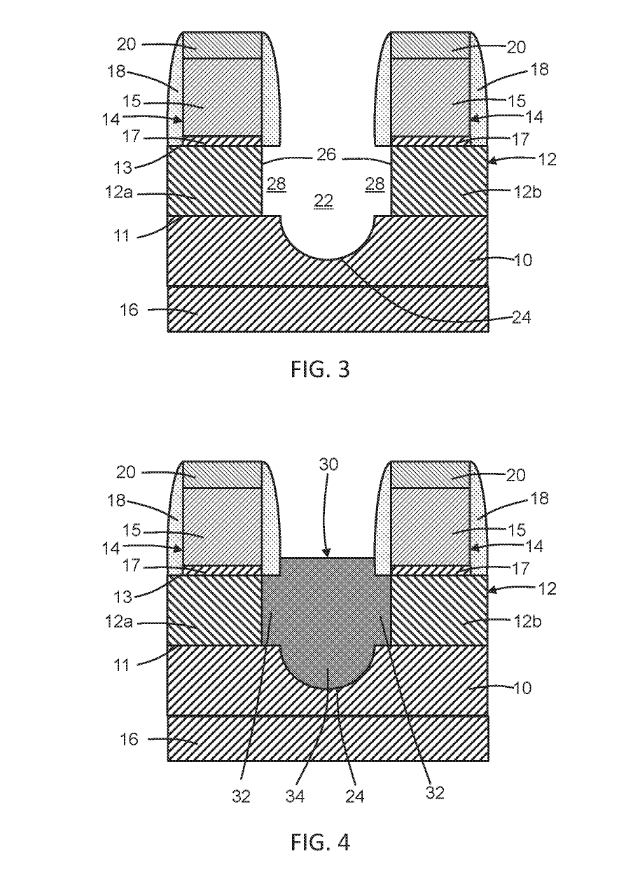

With reference to FIG. 3 in which like reference numerals refer to like features in FIG. 2 and at a subsequent fabrication stage of the processing method, the side surfaces 26 of the channel regions 12a, 12b of the semiconductor fin 12 are recessed laterally relative to the portion of the cavity 22 in the substrate fin 10 by an isotropic etching process that removes the semiconductor material of the semiconductor fin 12 selective to (i.e., at a higher rate) than the semiconductor material of the substrate fin 10. Cavity extensions 28 of the cavity 22 are formed that extend laterally beneath the sidewall spacers 18 and, depending on the degree of undercutting, the gate structures 14 as well. The isotropic etching process operates to increase the width of the portion of the cavity 22 above the interface 11, which narrows the channel regions 12a, 12b and increases the distance between the side surfaces 26. The side surfaces 26 may retain their vertical orientation and planarity after the conclusion of the isotropic etching process. As a result, the widened portion of the cavity 22 above the interface 11 has a box shape, and the portion of the cavity 22 in the substrate fin 10 below the interface 11 has a rounded shape. The bottom surface 24 of the portion of the cavity 22 in the substrate fin 10 may be modified only to a minor extent by the isotropic etching process due to the etch selectivity.

The etching process may be a wet chemical etching process that relies on an etch chemistry such as a mixture of peroxide with a base, such as a mixture of water (H₂O), hydrogen peroxide (H₂O₂), and ammonium hydroxide (NH₄OH) (i.e., a hot SC1 clean), of buffered or dilute hydrochloride acid. Alternatively, the etching process may be a selective dry etch-back process. The lateral recessing of the semiconductor fin 12 decreases the gate length and increases the proximity of subsequently-formed source/drain regions to the channel regions 12a, 12b.

With reference to FIG. 4 in which like reference numerals refer to like features in FIG. 3 and at a subsequent fabrication stage of the processing method, an embedded source/drain region 30 is formed in the cavity 22 and adopts the shape of the cavity 22 and its associated cavity extensions 28. The embedded source/drain region 30 is comprised of epitaxial semiconductor material that is grown in the cavity 22 and in the cavity extensions 28 that extend the cavity 22 laterally outward. The embedded source/drain region 30 includes sections 32 that are located in the cavity extensions 28 above the interface 11, and a section 34 that is located in the portion in the cavity 22 in the substrate fin 10 below the interface 11. The sections 32 have a thickness that is greater than or equal to the thickness of the semiconductor fin 12 (i.e., the thickness of the channel regions 12a, 12b), and have a height equal to the distance from the interface 11 to the top surface 13.

An epitaxial growth process may be used to deposit semiconductor material, such as silicon germanium (SiGe) or carbon-doped silicon (Si:C), to form the embedded source/drain region 30, and may include in situ doping during growth to impart a given conductivity type to the grown semiconductor material. In an embodiment, the embedded source/drain region 30 may be formed by a selective epitaxial growth process in which semiconductor material nucleates for epitaxial growth on semiconductor surfaces, but does not nucleate for epitaxial growth from insulator surfaces. As used herein, the term “source/drain region” means a doped region of semiconductor material that can function as either a source or a drain of a field-effect transistor. For a p-type field-effect transistor, the semiconductor material of the embedded source/drain region 30 may be doped with a p-type dopant selected from Group III of the Periodic Table (e.g., boron (B)) that is effective to impart p-type conductivity. For an n-type field-effect transistor, the semiconductor material of the embedded source/drain region 30 may be doped with an n-type dopant from Group V of the Periodic Table (e.g., phosphorus (P) or arsenic (As)) that is effective to impart n-type conductivity.

The embedded source/drain region 30 may be strained and incorporate internal stress through control over the conditions and parameters characterizing the epitaxial growth process. The embedded source/drain region 30 may operate as stressors that transfer stress to the channel regions 12a, 12b of the semiconductor fin 12 such that the channel regions 12a, 12b are placed under stain, which may increase carrier mobility in channels formed during device operation. If the embedded source/drain region 30 is composed of Si:C, tensile strain may be produced in the channel regions 12a, 12b, which may be appropriate for an n-type field-effect transistor. If the embedded source/drain region 30 is composed of SiGe, compressive strain may be produced in the channel regions 12a, 12b, which may be appropriate for a p-type field-effect transistor.

The formation of the cavity 22 with two distinct etching processes of different characteristics, isotropy and anisotropy, decouples the depth of the cavity 22 from the proximity of the cavity to the channel region 12a or channel region 12b of the field-effect transistor. The widening of the cavity 22 by the isotropic etching process defines the proximity of the source and drain junctions, and also places the stress from the epitaxial semiconductor material of the embedded source/drain region 30 in the widened portion of the cavity 22 closer to the channel region 12a or channel region 12b. The depth of the cavity 22 may be increased to further scale volume/strain without impacting electrostatics (e.g., without introducing a drain-induced barrier lowering (DIBL) penalty or an off-state leakage current (Ioff) penalty).

The methods as described above are used in the fabrication of integrated circuit chips. The resulting integrated circuit chips can be distributed by the fabricator in raw wafer form (e.g., as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case, the chip may be integrated with other chips, discrete circuit elements, and/or other signal processing devices as part of either an intermediate product or an end product.

References herein to terms such as “vertical”, “horizontal”, etc. are made by way of example, and not by way of limitation, to establish a frame of reference. The term “horizontal” as used herein is defined as a plane parallel to a conventional plane of a semiconductor substrate, regardless of its actual three-dimensional spatial orientation. The terms “vertical” and “normal” refer to a direction perpendicular to the horizontal, as just defined. The term “lateral” refers to a direction within the horizontal plane. Terms such as “above” and “below” are used to indicate positioning of elements or structures relative to each other as opposed to relative elevation.

A feature “connected” or “coupled” to or with another element may be directly connected or coupled to the other element or, instead, one or more intervening elements may be present. A feature may be “directly connected” or “directly coupled” to another element if intervening elements are absent. A feature may be “indirectly connected” or “indirectly coupled” to another element if at least one intervening element is present.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A method for forming a fin-type field-effect transistor, the method comprising:
forming a semiconductor fin and a substrate fin underlying the semiconductor fin;
forming a first gate structure and a second gate structure that overlap with a respective channel region in the semiconductor fin;
etching the semiconductor fin with a first etching process to form a cavity with a first portion in the semiconductor fin and a second portion in the substrate fin; and
after the cavity is formed, etching the semiconductor fin selective to the substrate fin with a second etching process to widen the first portion of the cavity,
wherein the cavity is self-aligned in the semiconductor fin and the substrate fin between the first gate structure and the second gate structure, the first portion of the cavity has a box shape, the second portion of the cavity has a rounded shape, the semiconductor fin is composed of silicon-germanium, and the substrate fin is composed of silicon.

2. The method of claim 1 wherein the second etching process is an isotropic etching process.

3. The method of claim 2 wherein the isotropic etching process is a wet chemical etching process.

4. The method of claim 2 wherein the first etching process is an anisotropic etching process.

5. The method of claim 2 wherein the isotropic etching process is a dry etching process.

6. (canceled)

7. The method of claim 1 further comprising:
epitaxially growing an embedded source/drain region in the cavity,
wherein a portion of the embedded source/drain region extends into the first portion of the cavity that is widened.

8. The method of claim 7 wherein the embedded source/drain region includes internal stress that is transferred to the channel region in the semiconductor fin.

9. The method of claim 8 wherein the embedded source/drain region is composed of silicon-germanium, the field-effect transistor is a p-type field effect transistor, and the embedded source/drain region transfers compressive strain to the channel region.

10. The method of claim 8 wherein the embedded source/drain region is composed of carbon-doped silicon, the field-effect transistor is an n-type field effect transistor, and the embedded source/drain region transfers tensile strain to the channel region.

11. The method of claim 8 wherein the embedded portion of the source/drain region in the first portion of the cavity has a thickness greater than or equal to a thickness of the channel region.

12-17. (canceled)

18. The method of claim 1 wherein the semiconductor fin and the substrate fin converge along an interface, the first portion of the cavity is located above the interface, and the second portion of the cavity is located below the interface.

19. The method of claim 1 wherein the gate structure includes a gate electrode, and further comprising:
forming a sidewall spacer on a vertical sidewall of the gate electrode,
wherein the first portion of the cavity undercuts the sidewall spacer.

20. The method of claim 19 wherein the first etching process is self-aligned by the sidewall spacer, and the second etching process is isotropic.
